(19) United States
(12) Patent Application Publication
(10) Pub. No.: US 2025/0087450 A1
(43) Pub. Date: Mar. 13, 2025

(54) Optics for In-Situ Scanning Electron Microscope Repair

(71) Applicant: KLA Corporation, Milpitas, CA (US)

(72) Inventors: Tomas Plettner, Danville, CA (US); Lesther Moreira Osorio, San Jose, CA (US); Kenneth Leedle, Mountain View, CA (US); Hamada Wahba, Gilroy, CA (US); Joseph Hijazi, Santa Clara, CA (US); Earl Jensen, Santa Clara, CA (US); Rush Ogden, San Jose, CA (US); Oersan Yueksek, Langen (DE); Maseeh Mukhtar, San Jose, CA (US)

(21) Appl. No.: 18/542,072

(22) Filed: Dec. 15, 2023

Related U.S. Application Data
(60) Provisional application No. 63/538,071, filed on Sep. 13, 2023.

(51) Int. Cl. H01J 37/28; H01J 37/147; H01J 37/21; H01J 37/22; H01J 37/24

(52) U.S. Cl. CPC H01J 37/28; H01J 37/1475; H01J 37/21; H01J 37/228; H01J 37/24

(57) ABSTRACT

An apparatus is loaded into a scanning electron microscope (SEM) through a load lock of the SEM and onto a stage of the SEM. The apparatus includes a substrate and also includes optics, mechanically coupled to the substrate, to direct light upward away from the substrate. With the apparatus on the stage of the SEM, the optics are used to direct the light upward through an aperture of the SEM onto an electron detector in the SEM.

### RELATED APPLICATION

This application claims the benefit of U.S. Provisional Patent Application No. 63/538,071, filed on Sep. 13, 2023, which is incorporated by reference in its entirety for all purposes.

### TECHNICAL FIELD

This disclosure relates to scanning electron microscopes (SEMs), and more specifically to optics used in situ to repair a SEM.

### BACKGROUND

SEMs include electron detectors that detect electron scattered from targets being imaged. The electron detectors are sometimes referred to as electron detection devices (EDDs). The electron detectors may be implemented as reverse-biased diodes. During SEM operation, charge trapping occurs in the electron detectors, resulting in the loss of detector bandwidth and thus impairment of the imaging capability of the SEM. A SEM with electron-detector bandwidth degradation may be repaired by replacing the entire subsystem (i.e., field-replaceable unit or FRU) in the SEM that includes the electron detector(s). This approach is costly and labor-intensive, and incurs significant down-time for the SEM. Another approach is to reverse the electron-detector bandwidth degradation through elevated-temperature treatment, which is also labor-intensive and also incurs significant down-time.

### SUMMARY

According, there is a need for more practical techniques for recovering lost electron-detector bandwidth. In particular, it is desirable to repair electron detectors in situ without breaking the vacuum for the SEM.

In some embodiments, an apparatus includes a substrate and also includes optics, mechanically coupled to the substrate, to direct light upward away from the substrate into an aperture of a SEM. The apparatus is loadable into the SEM and unloadable from the SEM through a load lock of the SEM.

In some embodiments, a method includes loading an apparatus into a SEM through a load lock of the SEM and onto a stage of the SEM. The apparatus includes a substrate and also includes optics, mechanically coupled to the substrate, to direct light upward away from the substrate. The method also includes, with the apparatus on the stage of the SEM, using the optics to direct the light upward through an aperture of the SEM onto an electron detector in the SEM.

This apparatus and method may be used to perform maintenance in situ on electron detectors to recover lost bandwidth, and may also be used to test electron detectors in situ.

### BRIEF DESCRIPTION OF THE DRAWINGS

For a better understanding of the various described implementations, reference should be made to the Detailed Description below, in conjunction with the following drawings.

FIG. 1 is a cross-sectional view of an apparatus, including a light source, lens, and mirror disposed in a container, that has been loaded onto a stage in a vacuum chamber of a SEM to illuminate an electron detector in the SEM, in accordance with some embodiments.

FIG. 2 is a cross-sectional view of an apparatus, including a light source, lens, and mirror mounted on a substrate, that has been loaded onto a stage in a vacuum chamber of a SEM to illuminate an electron detector in the SEM, in accordance with some embodiments.

FIG. 3 illustrates insertion of the apparatus of FIG. 1 into a SEM through a load lock of the SEM, in accordance with some embodiments.

FIG. 4 illustrates insertion of the apparatus of FIG. 2 into a SEM through a load lock of the SEM, in accordance with some embodiments.

FIG. 5 is a cross-sectional view of an apparatus, including a lens and mirror disposed in a container and omitting a light source, that has been loaded onto a stage in a vacuum chamber of a SEM to illuminate an electron detector in the SEM, in accordance with some embodiments.

FIG. 6 is a cross-sectional view of an apparatus, including a lens and mirror mounted on a substrate and omitting a light source, that has been loaded onto a stage in a vacuum chamber of a SEM to illuminate an electron detector in the SEM, in accordance with some embodiments.

FIG. 7 illustrates insertion of the apparatus of FIG. 5 or FIG. 6 into a SEM through a load lock of the SEM, in accordance with some embodiments.

FIG. 8 is a block diagram showing components of an example of the apparatus of FIG. 1 or FIG. 2, in accordance with some embodiments.

FIG. 9 is a block diagram showing components of another example of the apparatus of FIG. 1 or FIG. 2, in accordance with some embodiments.

FIG. 10 is a flowchart illustrating a method of illuminating an electron detector in a SEM in accordance with some embodiments.

Like reference numerals refer to corresponding parts throughout the drawings and specification.

### DETAILED DESCRIPTION

Reference will now be made in detail to various embodiments, examples of which are illustrated in the accompanying drawings. In the following detailed description, numerous specific details are set forth in order to provide a thorough understanding of the various described embodiments. However, it will be apparent to one of ordinary skill in the art that the various described embodiments may be practiced without these specific details. In other instances, well-known methods, procedures, components, circuits, and networks have not been described in detail so as not to unnecessarily obscure aspects of the embodiments.

Bandwidth degradation of an electron detector in a SEM may be reversed in situ by illuminating the electron detector. The electron detector may be illuminated using an apparatus that is loaded into the SEM through a load lock. The electron detector thus may be repaired without breaking vacuum in the SEM and without replacing the subsystem of the SEM that includes the electron detector. Illumination of an electron detector may also be performed to test the functionality of the electron detector with light.

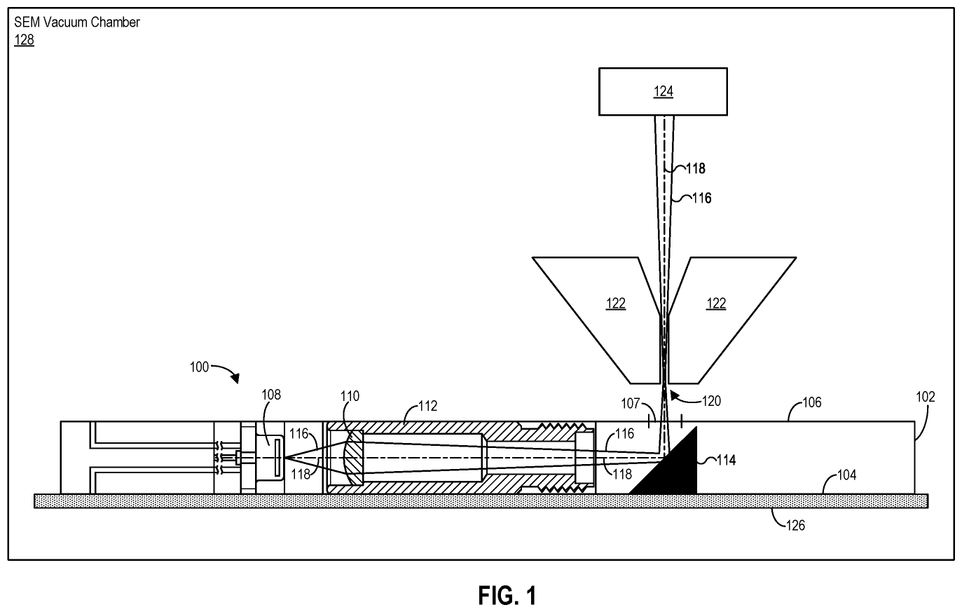

FIG. 1 is a cross-sectional view of an apparatus 100 used to illuminate an electron detector 124 in a SEM, in accordance with some embodiments. In FIG. 1, the apparatus 100 has been loaded onto a stage 126 in a vacuum chamber 128 of the SEM. During regular operation of the SEM, targets may be loaded onto the stage 126 for imaging. In some embodiments, these targets are reticles (i.e., photomasks) used to fabricate semiconductor wafers; the SEM may be configured and used to image the reticles (e.g., to inspect reticles for defects and/or to image defects that have been identified on inspected reticles). The apparatus 100 is not used during regular operation, however, but instead is used to perform maintenance on the SEM and/or to test the SEM.

The apparatus 100 includes a container 102, light source 108, lens 110, and mirror 114. The light source 108, lens 110, and mirror 114 are disposed in the container 102. In some embodiments, the light source 108 is a laser (e.g., laser diode) or light-emitting diode (LED), the lens 110 is disposed in an optical component 112 (e.g., a collimator, which may be a fiber-optic collimator) in the container 102, and/or the mirror 114 is a right-angle prism mirror. For example, the light source 108 may be a Thorlabs L375P70MLD laser diode, the optical component 112 may be an Edmund Optics #88-173 fiber-optic collimator, and the mirror 114 may be a Thorlabs MRA05-F01 right-angle prism mirror.

The container 102 is reticle-shaped or otherwise shaped to allow the container 102 to be loaded into the SEM (e.g., into a SEM configured and used to image reticles) and onto the stage 126. The container 102 has a bottom surface that serves as a substrate 104 to which the light source 108, lens 110, and mirror 114 are mechanically coupled, directly or indirectly. For example, the light source 108, mirror 114, and/or optical component 112 that includes the lens 110 may be fastened and thus directly mechanically coupled to the substrate 104. In another example, the light source 108, optical component 112, and/or mirror 114 may be fastened to one or more sides of the container 102 and thus indirectly mechanically coupled to the substrate 104, since the sides of the container 102 are connected to the substrate 104 (i.e., to the bottom surface of the container 102).

The optical component 112 and mirror 114, and thus the lens 110 and mirror 114, entirely or partially compose optics that are disposed within the container 102 and are directly or indirectly mechanically coupled to the substrate 104. These optics direct light 116 upward away from the substrate 104 into an aperture 120 in the SEM and onto an electron detector 124 in the SEM. The container 102 has a top opening that allows the light 116 to be directed upward away from the substrate 104 into the aperture 120. For example, the container 102 has an opening 107 (e.g., an aperture or window) in a top surface 106 of the container 102. In another example, the top surface 106 of the container 102 is absent, such that the top of the container 102 is open.

Directing the light 116 into the aperture 120 directs the light 116 into the column of the SEM. For example, the mirror 114 may direct the light 116 upward away from the substrate 104 (e.g., at a right angle to the substrate 104) through the aperture 120 into the column of the SEM. The aperture 120 may be an opening in a lens 122 (e.g., a magnetic lens) used during regular operation to focus electrons onto a target being imaged, with the target being mounted on the stage 126 during regular operation. The electron detector 124 is used during regular operation to detect secondary electrons scattered from the surface of the target being imaged.

The lens 110 may guide the light 116 to the mirror 114 along an optical path that is substantially parallel to the substrate 104. The optical path corresponds to an optic axis 118 that is parallel to the substrate 104 between the lens 110 and the mirror 114. The mirror 114 changes the direction of the optic axis 118 and optical path (e.g., by 90 degrees upward away from the substrate 104); the optic axis 118 then passes through the aperture 118 and terminates at the electron detector 124, such that light 116 illuminates the electron detector 124. The stage 126 is positioned in the vacuum chamber 128 with the mirror 114 situated in line of sight with the electron detector 124 through the aperture 120. In some embodiments, the lens 110 focuses the light 116 into the aperture 120 (e.g., such that substantially all the light 116 passes through the aperture 120 and on to the electron detector 124). In some embodiments, the lens 110 collimates the light 116 (e.g., such that a collimated beam of light is incident on the aperture 120; the collimated beam may be wider than the aperture 120, such that only a portion of the collimated beam passes through the aperture 120 and on to the electron detector 124).

The light source 108 generates the light 116 (e.g., a laser beam or LED light) and provides the light 116 to the lens 110 (e.g., to the optical component 112) along the optical path that corresponds to the optic axis 118. The portion of the optic axis 118 between the light source 108 and the lens 110 may be parallel to the substrate 104 (e.g., along with the portion of the optic axis 118 between the lens 110 and the mirror 114). The light source 108 thus provides the light 116 to the optics that guide the light 116 along the optical path. The optical path may first be substantially parallel to the substrate 104 and is then oriented upward away from the substrate 104.

The power and wavelength(s) of the light source 108 are chosen to allow effective charge de-trapping to occur for the electron detector 124, in accordance with some embodiments. For example, the light source 108 generates the light 116 with power between 1 mW and 100 mW and with a wavelength (or wavelengths) in a range between 250 nm and 600 nm. For example, the wavelength(s) may be ultraviolet, or violet, or blue, or green, or yellow, or orange. Too low of a power for the light 116 causes the charge de-trapping to take too long and therefore to be impractical, whereas too high of a power for the light 116 may damage components in the SEM. Similarly, too long of a wavelength for the light 116 may cause the light 116 to be ineffective for charge de-trapping, whereas too short of a wavelength for the light 116 may damage components in the SEM.

The light source 108 may be configurable to operate in multiple power states (i.e., modes). For example, the light source 108 may be operated in a first, full-power state and a second, low-power state, with the power of the light 116 generated in the first, full-power state being higher than the power of the light 116 generated in the second, low-power state. The light source 108 may also be turned off and thus placed in an off state. The first, full-power state may be used for charge de-trapping. The second, low-power state may be used to align the apparatus 100 (e.g., the mirror 114) with the aperture 120. Alignment is performed to position the apparatus 100 so that the optic axis 118, and thus light 116, passes through the aperture 120 to the electron detector 124. Alignment may be performed by operating the light source 108 in the second, low-power mode and moving the stage 126 until the electron detector 124 detects light 116. For example, the stage 126 may be an x-y stage with corresponding motors that translate the stage 126 until it is properly positioned. Once alignment is complete with the apparatus 100 properly positioned, the light source 108 is switched to the first, full-power state to perform charge de-trapping.

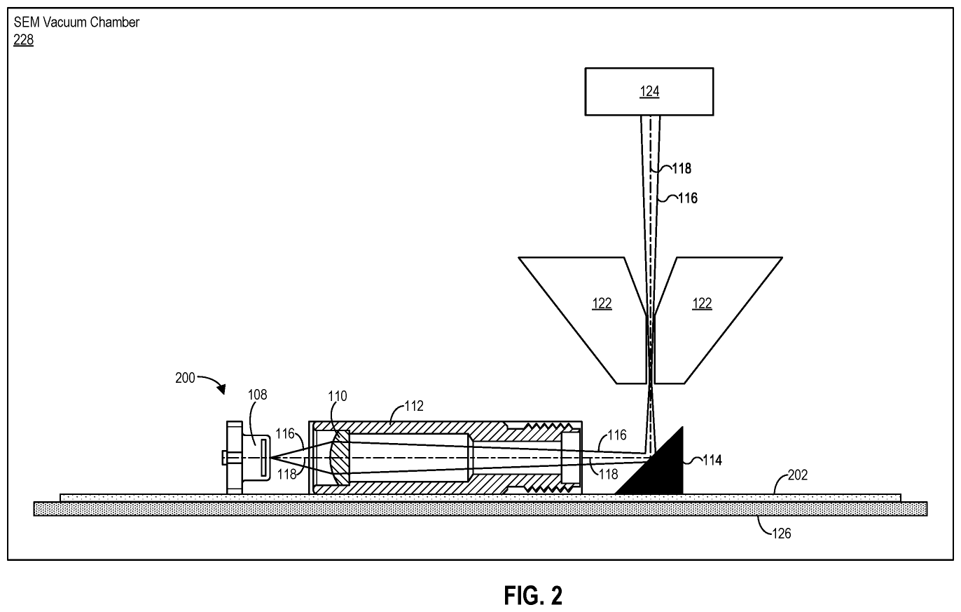

In some embodiments, the container 102 may be omitted. FIG. 2 is a cross-sectional view of an apparatus 200 in which the container 102 has been omitted and the substrate 104 is replaced with a substrate 202, in accordance with some embodiments. The light source 108, lens 110, and mirror 114 are mechanically coupled to the substrate 202 by being mounted on top of the substrate 202. For example, the light source 108, optical component 112, and/or mirror 114 may be directly mechanically coupled (e.g., fastened) to the substrate 202.

In FIG. 2, the apparatus 200 has been loaded onto a stage 126 in a vacuum chamber 228 of a SEM, in accordance with some embodiments. Targets may be loaded onto the stage 126 in the vacuum chamber 228 for imaging during regular operation of the SEM. In some embodiments, these targets are semiconductor wafers; the SEM may be referred to as a wafer SEM. The apparatus 200 is not used during regular operation, however, but instead is used to perform maintenance on the SEM or to test the SEM. The substrate 202 may be wafer-shaped or otherwise shaped to allow the apparatus 200 to be loaded into the SEM and onto the stage 126. The light source 108, lens 110, optical component 112, and mirror 114 of the apparatus 200 function as described for the apparatus 100 (FIG. 1).

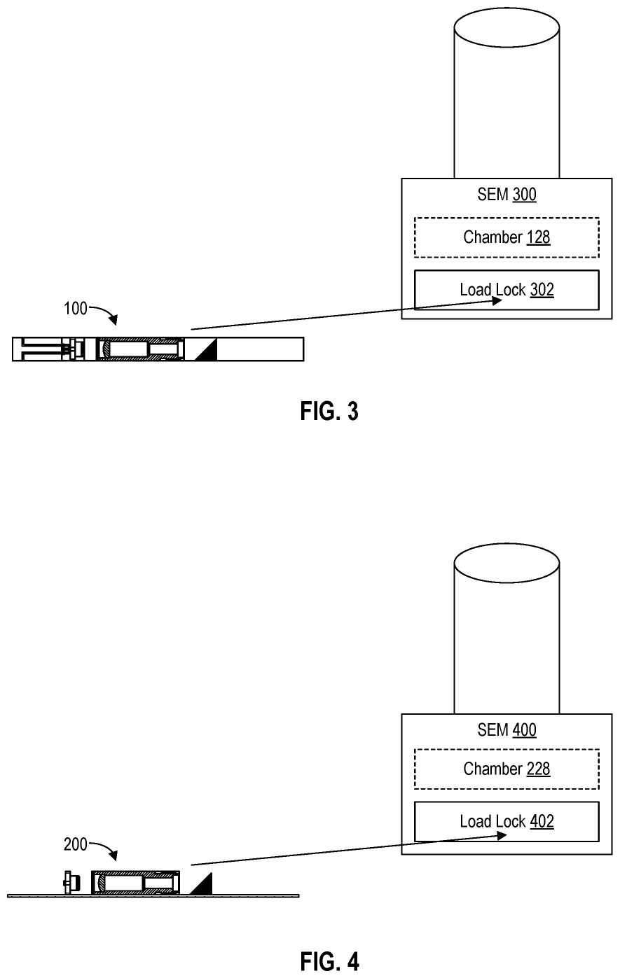

FIG. 3 illustrates insertion of the apparatus 100 (FIG. 1) into a SEM 300 through a load lock 302 of the SEM 300, in accordance with some embodiments. The SEM 300 includes a vacuum chamber 128 (FIG. 1). In some embodiments, the SEM 300 is configured, and used during regular operation, to image reticles, and the apparatus 100 is reticle-shaped or otherwise shaped to allow the apparatus 100 to be loaded into the vacuum chamber 128 of the SEM 300 through the load lock 302. The load lock 302 is separate from the vacuum chamber 128; the load lock 302 is directly accessible from outside the SEM 300, whereas the vacuum chamber 128 is not and instead is accessible through the load lock 302. The apparatus 100 is loaded into the SEM 300 through the load lock 302. With the load lock 302 at atmospheric pressure, the apparatus 100 is loaded from outside the SEM 300 into the load lock 302. With the apparatus 100 in the load lock 302, the load lock 302 is then pumped down to vacuum. Once a vacuum has been established in the load lock 302, the apparatus 100 is transferred into the vacuum chamber 128 and onto the stage 126 (FIG. 1). The apparatus 100 is aligned with the aperture 120 (FIG. 1) (e.g., using the second, low-power state for the light source 108) and then used to illuminate the electron detector 124 (FIG. 1) to perform maintenance on the electron detector 124 (e.g., using the first, full-power state for the light source 108) and/or to test the electron detector 124. Once the maintenance and/or testing are complete, the apparatus 100 is transferred back from the vacuum chamber 128 to the load lock 302 with the load lock 302 in vacuum, the load lock 302 is vented to atmospheric pressure, and the apparatus 100 is then removed from the load lock 302. In this manner, the apparatus 100 is loadable into the SEM 300 and unloadable from the SEM 300 through the load lock 302.

FIG. 4 illustrates insertion of the apparatus 200 (FIG. 2) into a SEM 400 through a load lock 402 of the SEM 400, in accordance with some embodiments. The SEM 400 includes a vacuum chamber 228 (FIG. 2) that is separate from the load lock 402; the load lock 402 is directly accessible from outside the SEM 400, whereas the vacuum chamber 228 is not and instead is accessible through the load lock 402. In some embodiments, the SEM 400 is configured, and used during regular operation, to image semiconductor wafers (e.g., the SEM 400 is a wafer SEM), and the apparatus 200 is wafer-shaped (e.g., has a wafer-shaped substrate 202, FIG. 2) or otherwise shaped to allow the apparatus 200 to be loaded into the vacuum chamber 228 of the SEM 400 through the load lock 402. The apparatus 200 is loadable into the SEM 400 (i.e., into the vacuum chamber 228) and unloadable from the SEM 400 (i.e., from the vacuum chamber 228) through the load lock 402 in the same manner that the apparatus 100 is loadable into and unloadable from the SEM 300 through the load lock 302 (FIG. 3).

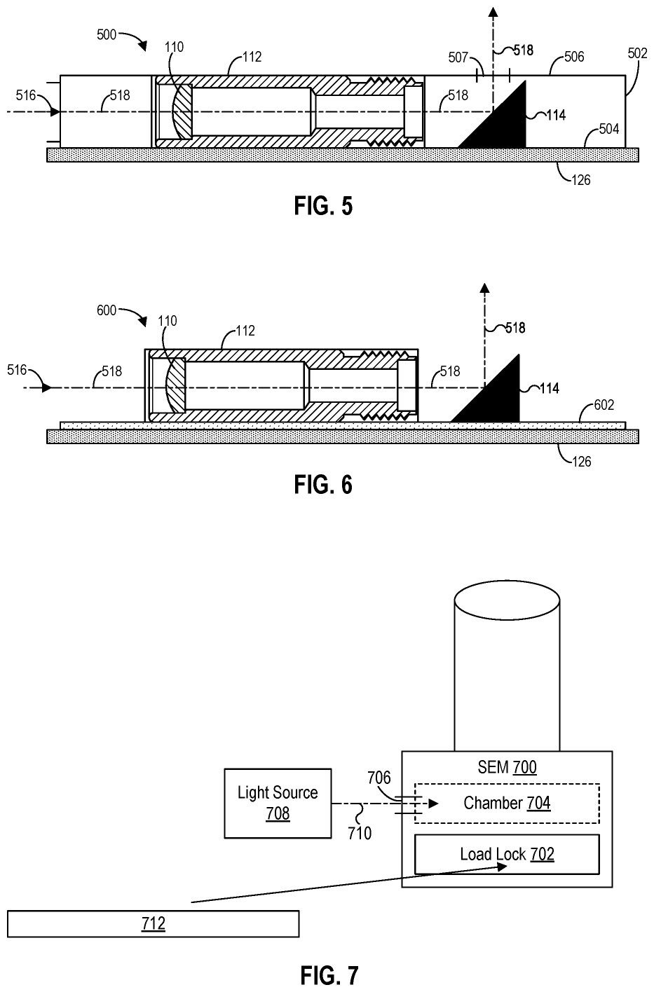

In some embodiments, the light source 108 is omitted from the apparatus 100 or 200. FIG. 5 is a cross-sectional view of an apparatus 500, used to illuminate an electron detector 124 in a SEM, that does not include the light source 108 in accordance with some embodiments. The apparatus 500 corresponds to the apparatus 100 (FIG. 1), but with the light source 108 omitted. The lens 110, optical component 112, and mirror 114 of the apparatus 500 are disposed in a container 502. The container 502 is reticle-shaped or otherwise shaped to allow the container 502 to be loaded into the SEM, which may be configured and used to image reticles. The container 502 has a bottom surface that serves as a substrate 504 to which the lens 110 and mirror 114 are mechanically coupled, directly or indirectly. For example, the mirror 114 and/or optical component 112 that includes the lens 110 may be fastened and thus directly mechanically coupled to the substrate 504. In another example, the optical component 112 and/or mirror 114 may be fastened to one or more sides of the container 502 and thus indirectly mechanically coupled to the substrate 504, since the sides of the container 502 are connected to the substrate 504 (i.e., to the bottom surface of the container 502).

The optics on the apparatus 500 function as described for the apparatus 100 (FIG. 1). Light 516 is provided to the optics on the apparatus 500 (i.e., to the lens 110 in the optical component 112 and onward to the mirror 114) from a light source that is separate from the apparatus 500. The separate light source may be external to the SEM or disposed within the SEM. The SEM has optics (e.g., fiber optics and/or free-space optics including mirrors) to direct the light 516 to the optics on the apparatus 500 along an optical path corresponding to an optic axis 518. The lens 110 may guide the light 516 to the mirror 114 along an optical path that is substantially parallel to the substrate 504. The optic axis 518 corresponding to this optical path is parallel to the substrate 504 between the lens 110 and the mirror 114. The mirror 114 changes the direction of the optic axis 118 and optical path (e.g., by 90 degrees upward away from the substrate 504), directing the light 516 upward away from the substrate 504. The container 502, like the container 102 (FIG. 1), has a top opening that allows the light 516 to be directed upward away from the substrate 504 into an aperture 120 (FIG. 1). For example, the container 502 has an opening 507 (e.g., an aperture or window) in a top surface 506 of the container 502. In another example, the top surface 506 of the container 502 is absent, such that the top of the container 502 is open.

FIG. 6 is a cross-sectional view of an apparatus 600, used to illuminate an electron detector 124 in a SEM, that corresponds to the apparatus 200 (FIG. 2) but with the light source 108 omitted, in accordance with some embodiments. The lens 110 and mirror 114 of the apparatus 600 are mechanically coupled to a substrate 602 by being mounted on top of the substrate 602. For example, the optical component 112 and/or mirror 114 may be directly mechanically coupled (e.g., fastened) to the substrate 602. The substrate 602 may be wafer-shaped or otherwise shaped to allow the apparatus 200 to be loaded into the SEM, which may be a wafer SEM. The optics on the apparatus 600, including the lens 110, optical component 112, and mirror 114, function as described for the apparatus 100 (FIG. 1), 200 (FIGS. 2), and 500 (FIG. 5).

FIG. 7 illustrates insertion of an apparatus 712 into a SEM 700 through a load lock 702 of the SEM 700, in accordance with some embodiments. The apparatus 712 includes a substrate and optics to direct light upward away from the substrate, but does not include a light source to generate the light. For example, the substrate 712 may be the substrate 500 (FIG. 5) or 600 (FIG. 6). In some embodiments, the SEM 700 is configured, and used during regular operation, to image reticles. In some embodiments, the SEM 700 is a wafer SEM.

The SEM 700 includes a vacuum chamber 704 that includes an electron detector (e.g., electron detector 124), an aperture (e.g., aperture 120 in a lens 122), and a stage (e.g., stage 126). The load lock 702 is separate from the vacuum chamber 704; the load lock 702 is directly accessible from outside the SEM 700, whereas the chamber 704 is not and instead is accessible through the load lock 702. The apparatus 700 is loadable into the SEM 700 (i.e., into the vacuum chamber 704) and unloadable from the SEM 700 (i.e., from the vacuum chamber 704) through the load lock 702 in the same manner that the apparatus 100 is loadable into and unloadable from the SEM 300 through the load lock 302 (FIG. 3) and that the apparatus 200 is loadable into and unloadable from the SEM 400 through the load lock 402 (FIG. 4).

A light source 708 (e.g., a laser or LED) that is external to the SEM 700 generates light 710 (e.g., light 516, FIG. 5 or 6), which is transmitted through a port 706 (e.g., a window or fiber-optic coupling) in the SEM 700 into the vacuum chamber 704. The light 710 is provided to the apparatus 712 when the apparatus 712 has been loaded into the vacuum chamber 704. The SEM 700 has optics (e.g., fiber optics and/or free-space optics including mirrors) to direct the light 710 to the optics on the apparatus 700 (e.g., along an optical path 518, FIGS. 5-6). The light source 708, like the light source 108, may be configurable to operate in multiple power states (i.e., modes). For example, the light source 708, like the light source 108, may have a first, full-power state; a second, low-power state; and an off state. The power of the light 710 generated in the first, full-power state is higher than the power of the light 710 generated in the second, low-power state. The power and wavelength(s) of the light 710 generated by the light source 708 may be the same as the power and wavelength(s) of the light 116 generated by the light source 108 (FIGS. 1-2).

In some embodiments, the light source 708 may be disposed inside the SEM 700 instead of outside the SEM 700 and the port 706 may be omitted.

The apparatus 100 (FIGS. 1, 3) may have additional components beyond the light source 108, lens 110, optical component 112, and mirror 114. The additional components may be disposed in the container 102. Similarly, the apparatus 200 (FIGS. 2, 4) may have additional components, which may be mounted on the substrate 202.

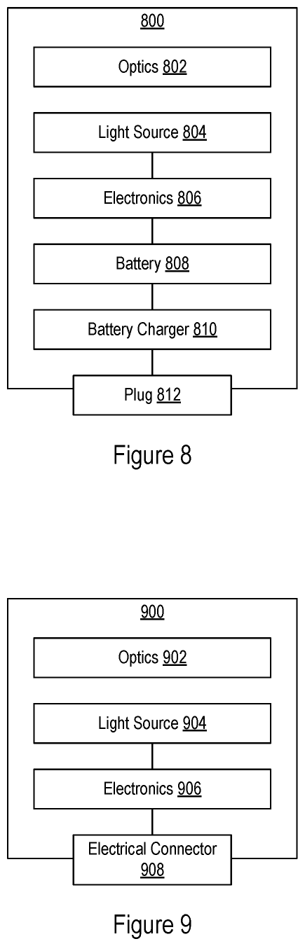

FIG. 8 is a block diagram showing components of an apparatus 800 in accordance with some embodiments. The apparatus 800 may be an example of the apparatus 100 (FIG. 1, 3) or 200 (FIGS. 2, 4). The apparatus 800 has a substrate (e.g., substrate 104, FIG. 1; substrate 202, FIG. 2) to which the components shown in FIG. 8 are mechanically coupled, directly or indirectly. These components of the apparatus 800 include optics 802 (e.g., lens 110 and mirror 114; lens 110, optical component 112, and mirror 114), a light source 804 (e.g., light source 108), electronics 806, a battery 808, a battery charger 810, and a plug 812. The electronics 806 are electrically coupled to the light source 804 and control the light source 804: the electronics 806 turn the light source 804 on and off and may be used to control the power of light generated by the light source 804 (e.g., by controlling the power provided to the light source 804). In some embodiments, the electronics 806 are used to switch the light source 804 between different states, including a first on state (e.g., the first, full-power state of the light source 108), a second on state (e.g., the second, low-power state of the light source 108) with lower power than the first on state, and an off state. The battery 808 is electrically coupled to the electronics 806 and the light source 804, to power the electronics 806 and the light source 804. The battery 808 may be electrically coupled to the light source 804 through the electronics 806, with the electronics 806 controlling the amount of power provided from the battery 808 to the light source 804.

The battery charger 810 is electrically coupled to the battery 808 to charge the battery 808. The battery charger 810 is also electrically coupled to the plug 812, through which the battery charger 810 receives power for charging the battery 808 (e.g., for recharging the battery 808 after the apparatus 800 has been used in a SEM). To charge the battery 808, the plug 812 is connected to (e.g., receives) a connector for a power supply that is external to the apparatus 800 and to the SEM. The plug 812 receives power for the battery charger 810 from this external power supply when the apparatus 800 is not in the SEM; the battery charger 810 uses this power to charge the battery 808.

FIG. 9 is a block diagram showing components of an apparatus 900 in accordance with some embodiments. The apparatus 900, like the apparatus 800 (FIG. 8), may be an example of the apparatus 100 (FIG. 1, 3) or 200 (FIGS. 2, 4). The apparatus 900 has a substrate (e.g., substrate 104, FIG. 1; substrate 202, FIG. 2) to which the components shown in FIG. 9 are mechanically coupled, directly or indirectly. These components of the apparatus 900 include optics 902 (e.g., lens 110 and mirror 114; lens 110, optical component 112, and mirror 114), a light source 904 (e.g., light source 108), electronics 906, and an electrical connector 908. The electronics 906 are electrically coupled to the light source 904 and control the light source 904, for example in the same way that the electronics 806 control the light source 804 (FIG. 8). The electrical connector 908 is electrically coupled to the electronics 906 and the light source 904, to power the electronics 906 and the light source 904. The electrical connector 908 receives power from a power supply of a SEM and provides the power to the electronics 906 and the light source 904. For example, the electrical connector 908 makes contact with electrical contacts in the SEM that are used during regular operation to bias a target being imaged. The electrical connector 908 receives power through these electrical contacts. The electrical connector 908 may be electrically coupled to the light source 904 through the electronics 906, with the electronics 906 controlling the amount of power provided to the light source 904.

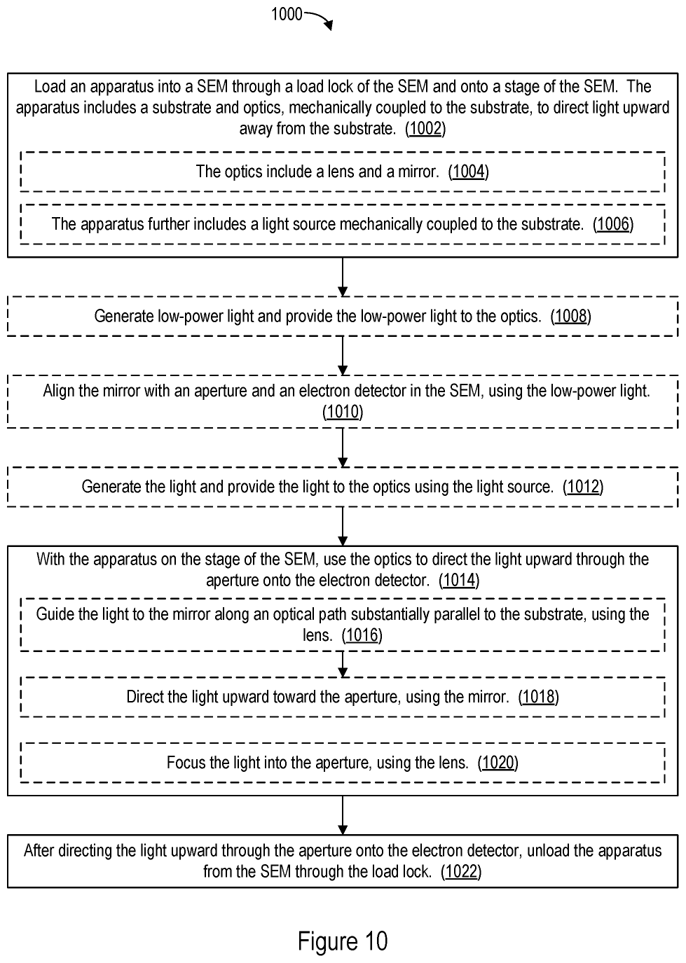

FIG. 10 is a flowchart illustrating a method 1000 of illuminating an electron detector in a SEM in accordance with some embodiments. In the method 1000, an apparatus is loaded (1002) into a SEM. Examples of the apparatus include the apparatus 100 (FIGS. 1, 3), 200 (FIGS. 2, 4), 500 (FIG. 5), 600 (FIG. 6), 712 (FIG. 7), 800 (FIGS. 8), and 900 (FIG. 9). Examples of the SEM include the SEM 300 (FIG. 3), 400 (FIGS. 4), and 700 (FIG. 7). The apparatus is loaded (1002) into the SEM through a load lock of the SEM (e.g., load lock 302, FIG. 3; 402, FIG. 4; 702, FIG. 7) and onto a stage of the SEM (e.g., stage 126, FIG. 1, 2, 5, or 6). The apparatus includes a substrate (e.g., substrate 104, FIG. 1; 202, FIG. 2; 504, FIG. 5; 602, FIG. 6) and optics (e.g., optics 802, FIG. 8; 902, FIG. 9), mechanically coupled to the substrate, to direct light upward away from the substrate. In some embodiments, the optics include (1004) a lens (e.g., lens 110, FIG. 1, 2, 5, or 6) and a mirror (e.g., mirror 114, FIG. 1, 2, 5, or 6). The apparatus may further include (1006) a light source (e.g., light source 108, FIG. 1 or 2; 804, FIG. 8; 904, FIG. 9) mechanically coupled to the substrate. Alternatively, the light source may be omitted (e.g., as for the apparatus 500, 600, and 712, FIGS. 5-7).

In some embodiments, with the apparatus loaded onto the stage, low-power light is generated and provided (1008) to the optics. Using the low-power light, the mirror is aligned (1010) with an aperture (e.g., aperture 122, FIG. 1 or 2) and an electron detector (e.g., electron detector 124, FIG. 1 or 2).

In some embodiments, with the apparatus on the stage after alignment has been performed (e.g., after the mirror has been aligned with the aperture and the electron detector in step 1010), light is generated and provided (1012) to the optics using the light source. Alternatively (e.g., if the light source is omitted from the apparatus), the light is received by the optics from a light source that is external to the apparatus (e.g., light source 708, FIG. 7). In either case, this light may be light of a first power (e.g., for the first, full-power state of the light source 108), the light in steps 1008 and 1010 may be light of a second power (e.g., for the second, low-power state of the light source 108), and the second power is lower than the first power: the low-power light is lower power than the full-power light.

With the apparatus on the stage after alignment has been performed, the optics are used (1014) to direct the light upward through the aperture (e.g., aperture 122, FIG. 1 or 2) onto the electron detector (e.g., electron detector 124, FIG. 1 or 2). In some embodiments, the light is guided (1016) to the mirror along an optical path substantially parallel to the substrate, using the lens, and is directed (1018) upward toward the aperture, using the mirror. In some embodiments, the light is focused (1020) into the aperture, using the lens. Alternatively, the light may be collimated using the lens, such that a collimated beam of light is incident on the aperture.

After directing the light upward through the aperture onto the electron detector, the apparatus is unloaded (1022) from the SEM through the load lock. For example, the apparatus is unloaded after the electron detector has been illuminated for a period of time sufficient to recover bandwidth through charge de-trapping, and/or after the electron detector has been tested using the light.

FIG. 10 shows steps in the method 1000 as being performed in a particular order. In practice, certain groups of steps may be performed simultaneously or may overlap. For example, steps 1008 and 1010 may be simultaneous or may overlap. Steps 1012 and 1014 also may be simultaneous or may overlap. But steps 1008 and 1010 are performed before steps 1012 and 1014, in accordance with some embodiments.

The foregoing description, for purpose of explanation, has been described with reference to specific embodiments. However, the illustrative discussions above are not intended to be exhaustive or to limit the scope of the claims to the precise forms disclosed. Many modifications and variations are possible in view of the above teachings. The embodiments were chosen in order to best explain the principles underlying the claims and their practical applications, to thereby enable others skilled in the art to best use the embodiments with various modifications as are suited to the particular uses contemplated.

What is claimed is:

1. An apparatus, comprising:
a substrate; and
optics, mechanically coupled to the substrate, to direct light upward away from the substrate into an aperture of a scanning electron microscope (SEM);
wherein the apparatus is loadable into the SEM and unloadable from the SEM through a load lock of the SEM.

2. The apparatus of claim 1, wherein the optics comprise:
a mirror to direct the light upward away from the substrate; and
a lens to guide the light to the mirror along an optical path substantially parallel to the substrate.

3. The apparatus of claim 2, wherein the lens is to focus the light into the aperture of the SEM.

4. The apparatus of claim 2, further comprising a light source, mechanically coupled to the substrate, to generate the light and provide the light to the optics.

5. The apparatus of claim 4, wherein the light source is a laser or a light-emitting diode (LED).

6. The apparatus of claim 4, wherein:
the light source is to generate the light in a wavelength range between 250 nm and 600 nm; and
the light source is to generate the light with power in a range between 1 mW and 100 mW.

7. The apparatus of claim 4, further comprising electronics, mechanically coupled to the substrate and electrically coupled to the light source, to control the light source, wherein:
the electronics are to switch the light source between a plurality of states;
the plurality of states comprises a first on state, a second on state, and an off state; and
the light to be generated by the light source in the first on state is higher power than the light to be generated by the light source in the second on state.

8. The apparatus of claim 7, further comprising a battery, mechanically coupled to the substrate and electrically coupled to the electronics and the light source, to power the electronics and the light source.

9. The apparatus of claim 8, further comprising:
a battery charger, mechanically coupled to the substrate and electrically coupled to the battery, to charge the battery; and
a plug, mechanically coupled to the substrate and electrically coupled to the battery charger, to receive power for the battery charger when the apparatus is not in the SEM.

10. The apparatus of claim 7, further comprising an electrical connector, mechanically coupled to the substrate and electrically coupled to the electronics and the light source, to receive power from a power supply of the SEM and to provide the power to the electronics and the light source.

11. The apparatus of claim 1, wherein the apparatus does not include a light source to generate the light.

12. The apparatus of claim 1, comprising a container that contains the optics, wherein:
the container is reticle-shaped;
the substrate is a bottom surface of the container;
the optics are disposed within the container; and
the container has a top opening to allow the optics to direct the light upward into the aperture.

13. The apparatus of claim 1, wherein:
the substrate is wafer-shaped; and
the optics are mounted on top of the substrate.

14. A method, comprising:
loading an apparatus into a scanning electron microscope (SEM) through a load lock of the SEM and onto a stage of the SEM, the apparatus comprising:
a substrate; and
optics, mechanically coupled to the substrate, to direct light upward away from the substrate; and
with the apparatus on the stage of the SEM, using the optics to direct the light upward through an aperture of the SEM onto an electron detector in the SEM.

15. The method of claim 14, further comprising, after directing the light upward through the aperture onto the electron detector, unloading the apparatus from the SEM through the load lock.

16. The method of claim 14, wherein:
the optics comprise a lens and a mirror; and
using the optics to direct the light upward through the aperture comprises:
guiding the light to the mirror along an optical path substantially parallel to the substrate, using the lens;
directing the light upward toward the aperture, using the mirror; and
focusing the light into the aperture, using the lens.

17. The method of claim 16, wherein:
the apparatus further comprises a light source mechanically coupled to the substrate; and
the method further comprises generating the light and providing the light to the optics using the light source.

18. The method of claim 17, wherein:
the light is light of a first power; and
the method further comprises, before generating, providing, guiding, directing, and focusing the light of the first power:
generating light of a second power and providing the light of the second power to the optics, wherein the second power is lower power than the first power, and wherein the mirror directs the light of the second power upward away from the substrate; and
aligning the mirror with the aperture and the electron detector, using the light of the second power.

19. The method of claim 14, wherein:
the SEM is configured to image reticles;
the container is reticle-shaped;
the substrate is a bottom surface of the container;
the optics are disposed within the container,
the container has a top opening; and
using the optics to direct the light upward comprises directing the light through the top opening.

20. The method of claim 14, wherein:
the SEM is configured to image semiconductor wafers;
the substrate is wafer-shaped; and
the optics are mounted on top of the substrate.
